(19) United States
(12) Patent Application Publication
(10) Pub. No.: US 2023/0392262 A1
(43) Pub. Date: Dec. 7, 2023

(54) SUBSTRATE PROCESSING APPARATUS AND SUBSTRATE PROCESSING METHOD

(71) Applicant: TES CO., LTD, Yongin-si (KR)

(72) Inventor: Tae-Kwang KIM, Yongin-si (KR)

(73) Assignee: TES CO., LTD, Yongin-si (KR)

(21) Appl. No.: 18/204,349

(22) Filed: May 31, 2023

(30) Foreign Application Priority Data
Jun. 2, 2022 (KR) 10-2022-0067876
Aug. 9, 2022 (KR) 10-2022-0099335

(51) Int. Cl. C23C 16/54; C23C 16/52; C23C 16/26; C23C 16/455; C23C 16/46

(52) U.S. Cl. CPC C23C 16/54; C23C 16/52; C23C 16/26; C23C 16/45519; C23C 16/463

(57) ABSTRACT

The present invention relates to a substrate processing apparatus and a substrate processing method, and more particularly to, a substrate processing apparatus and a substrate processing method capable of performing deposition on both upper and lower surfaces of a substrate in a single apparatus or a single facility when performing deposition on the lower surface of the substrate to alleviate or eliminate a bowing phenomenon of the substrate.

### BACKGROUND OF THE INVENTION

### Cross Reference to Related Application of the Invention

The present application claims the benefit of Korean Patent Application No. 10-2022-0067876 filed in the Korean Intellectual Property Office on Jun. 2, 2022, and Korean Patent Application No. 10-2022-0099335 filed in the Korean Intellectual Property Office on Aug. 9, 2022, the entire contents of which are incorporated herein by reference.

### FIELD OF THE INVENTION

The present invention relates to a substrate processing apparatus and a substrate processing method, and more particularly to, a substrate processing apparatus and a substrate processing method capable of performing deposition on both upper and lower surfaces of a substrate in a single apparatus or a single facility when performing deposition on the lower surface of the substrate to alleviate or eliminate a bowing phenomenon of the substrate.

### BACKGROUND OF THE RELATED ART

A substrate processing apparatus of the related art deposits a thin film having a predetermined thickness on one surface of a substrate, for example, an upper surface of the substrate.

In this case, when thin films are stacked on the substrate in a plurality of layers, such as a 3d-Nand device, the substrate may be bowed.

When a bowing phenomenon of the substrate occurs, it may be difficult to perform a process on the substrate at an accurate position in a subsequent process, and chucking the substrate may be difficult.

In particular, a substrate processing process includes works requiring very high precision, and the bowing phenomenon of the substrate may decrease the precision of the substrate process.

FIGS. 16A to 16C are diagrams for explaining a bowing phenomenon of a substrate W when a thin film is deposited on the substrate W.

FIG. 16A shows a case where a tensile stress is applied to the substrate W when a thin film 102 having a predetermined thickness is deposited on an upper surface of the substrate W, and conversely, FIG. 16B shows a case where a compressive stress is applied to the substrate W when the thin film 102 having the predetermined thickness is deposited on the upper surface of the substrate W.

As shown in FIG. 16A, when the tensile stress is applied to the substrate W, as shown in the figure, the substrate W is bowed downward, whereas as shown in FIG. 16B, when the compressive stress is applied to the substrate W, the substrate W is bowed upward.

In this case, in order to eliminate the bowing phenomenon of the substrate, the bowing phenomenon may be alleviated or eliminated by depositing a thin film 104 having a predetermined thickness on a lower surface of the substrate W as shown FIG. 16C.

The thin film 104 deposited on the lower surface of the substrate is configured as a thin film having the same stress as the thin film 102 deposited on the upper surface of the substrate.

However, with respect to the apparatus according to the related art, equipment depositing a thin film on the upper surface of a substrate and equipment depositing a thin film on the lower surface of the substrate are separately provided.

Therefore, a large area is required to install the equipment, and a significant amount of time is also required for the process.

In particular, when a substrate is transferred from the equipment depositing the thin film on the upper surface of the substrate to the equipment depositing the thin film on the lower surface of the substrate, the substrate is taken out from a vacuum environment inside a chamber of each equipment and transferred to a chamber of another apparatus.

In this case, a lot of time is required to build an environment inside the chamber, and in particular, a lot of time is required to build the vacuum environment inside the chamber.

### SUMMARY OF THE INVENTION

The present invention has been made in view of the above-mentioned problems occurring in the related art, and it is an object of the present invention to provide a substrate processing apparatus and a substrate processing method capable of performing deposition on both upper and lower surfaces of a substrate in a single apparatus or a single facility.

An object of the present invention as described above may be achieved by a substrate processing apparatus for performing a processing process on a substrate, the substrate processing apparatus including a transfer chamber transferring the substrate, a plurality of process chambers connected to the transfer chamber and performing the processing process on the substrate, and a control unit controlling driving of the plurality of process chambers, wherein some of the plurality of process chambers are configured as first process chambers depositing a thin film on an upper surface of the substrate, and the others are configured as second process chambers depositing a thin film on a lower surface of the substrate, and the first process chambers are symmetrically arranged with respect to the second process chambers and connected to the transfer chamber.

The number of the second process chambers may be less than or equal to the number of the first process chambers.

The control unit may store at least one of a size, a diameter, and a thickness of the substrate, information about a preprocessing process already performed on the substrate, information about a post-processing process to be performed later on the substrate, and information about a degree of bowing of the substrate according to the preprocessing process already performed on the substrate and an expected degree of bowing of the substrate according to the post-processing process to be performed later on the substrate, and the control unit may adjust the order and the number of repetitions of a first processing process of the first process chambers and a second processing process of the second process chambers on the substrate based on the stored information about the substrate.

The substrate processing apparatus may further include a sensing means sensing a thickness of the thin film on the upper surface or the lower surface of the substrate or a degree of bowing of the substrate, and the control unit may adjust the order and the number of repetitions of a first processing process of the first process chambers and a second processing process of the second process chambers on the substrate based on information sensed by the sensing means.

An amorphous carbon layer may be deposited on the upper surface of the substrate in the first process chambers.

The control unit may alternately repeat a first processing process of the first process chambers and a second processing process of the second process chambers on the substrate so that the amorphous carbon layer is deposited on the upper surface of the substrate to a desired thickness.

The substrate processing apparatus may further include a load lock chamber connected to the transfer chamber, and a temperature controller controlling a temperature of the substrate may be included in the load lock chamber.

An object of the present invention as described above may be achieved by a substrate processing apparatus for performing a processing process on a substrate, the substrate processing apparatus including a process chamber performing a processing process on the substrate, a plurality of stations provided inside the process chamber in which the substrate is seated and processed, and a control unit controlling driving of the plurality of stations, wherein some of the plurality of stations are configured as first stations depositing a thin film on an upper surface of the substrate, and the others are configured as second stations depositing a thin film on a lower surface of the substrate.

The plurality of stations may be partitioned by supplying a curtain gas such as an inert gas between the plurality of stations, or the plurality of stations may be physically partitioned but may be partitioned in a semi-enclosed or semi-isolated manner through which a movement of the substrate is possible.

The control unit may store at least one of a size, a diameter, and a thickness of the substrate, information about a preprocessing process already performed on the substrate, information about a post-processing process to be performed later on the substrate, and information about a degree of bowing of the substrate according to the preprocessing process already performed on the substrate and an expected degree of bowing of the substrate according to the post-processing process to be performed later on the substrate, and the control unit may adjust the order and the number of repetitions of a first processing process of the first process chambers and a second processing process of the second process chambers on the substrate based on the stored information about the substrate.

The substrate processing apparatus may further include a sensing means sensing a thickness of the thin film on the upper surface or the lower surface of the substrate or a degree of bowing of the substrate, and the control unit may adjust the order and the number of repetitions of a first processing process of the first process chambers and a second processing process of the second process chambers on the substrate based on information sensed by the sensing means.

The control unit may alternately repeat a first processing process of the first process chambers and a second processing process of the second process chambers on the substrate so that the amorphous carbon layer is deposited on the upper surface of the substrate to a desired thickness.

An object of the present invention as described above may be achieved by a substrate processing method of a substrate processing apparatus comprising a load lock chamber comprising a temperature controller controlling a temperature of a substrate, one or more first process chambers connected to the load lock chamber and depositing a thin film on an upper surface of the substrate, and one or more second process chambers depositing a thin film on a lower surface of the substrate, the substrate processing method including preheating the substrate to a first temperature in the load lock chamber, depositing the thin film on the upper surface of the substrate in the one or more first process chambers, cooling the substrate to a second temperature in the load lock chamber, and depositing a stress compensation layer on the lower surface of the substrate in the one or more second process chambers.

An amorphous carbon layer may be deposited on the upper surface of the substrate in the one or more first process chambers.

A process temperature of each of the one or more second process chambers may be lower than a process temperature of each of the one or more first process chambers.

The first temperature for preheating the substrate in the load lock chamber may be lower than a process temperature of each of the one or more first process chambers.

The second temperature may be set to be equal to the first temperature

The substrate processing method may further include, after depositing the stress compensation layer on the lower surface of the substrate in the one or more second process chambers, repeatedly transferring the substrate to the one or more first process chambers and depositing the thin film on the upper surface of the substrate.

### BRIEF DESCRIPTION OF THE DRAWINGS

FIG. 1 is a plan view of a substrate processing apparatus according to an embodiment of the present invention.

FIG. 2 is a schematic plan view illustrating the substrate processing apparatus of FIG. 1.

FIG. 3 is a plan view illustrating a transfer chamber and a process chamber in a substrate processing apparatus according to another embodiment.

FIG. 4 is a plan view of a substrate processing apparatus according to another embodiment of the present invention.

FIGS. 5 to 7 are diagrams illustrating a substrate processing method of the substrate processing apparatus of FIG. 4.

FIG. 8 is a plan view illustrating a transfer chamber and a process chamber in a substrate processing apparatus according to another embodiment.

FIGS. 9 to 13 are diagrams illustrating a substrate processing method according to FIG. 8.

FIGS. 14 and 15 are plan views of a substrate processing apparatus according to another embodiment.

FIGS. 16A to 16C are diagrams illustrating a bowing phenomenon of a substrate when a thin film is conventionally deposited on the substrate.

### DETAILED DESCRIPTION OF THE PREFERRED EMBODIMENTS

Hereinafter, a structure of a substrate processing apparatus 1000 according to the embodiment of the present invention will be described with reference to the drawings, and then a substrate processing method will be described in detail.

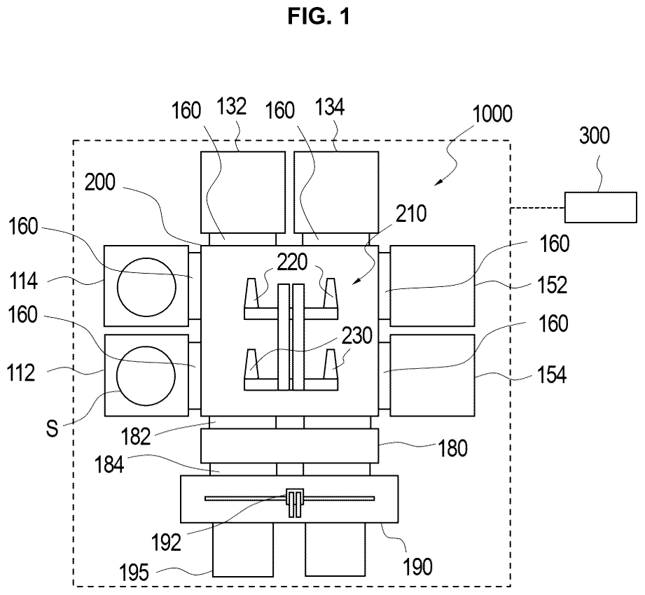

FIG. 1 is a plan view of the substrate processing apparatus 1000 according to an embodiment of the present invention.

Referring to FIG. 1, the substrate processing apparatus 1000 may include a load lock chamber 180 to which a substrate S is transferred, a transfer chamber 200 connected to the load lock chamber 180 to transfer the substrate S, a plurality of process chambers 112, 114, 132, 134, 152, and 154 connected to the transfer chamber 200 and performing a processing process on the substrate S, and a control unit 300 controlling driving of the process chambers 112, 114, 132, 134, 152, and 154.

In addition, the substrate processing apparatus 1000 may further include an atmospheric transfer module 190 in which a second transfer arm 192 is disposed, and at least one load port 195 for supporting a substrate seating portion (not shown) disposed outside the atmospheric transfer module 190 and in which substrates S are accommodated.

The substrate seating portion may be configured as a front opening unified pod (FOUP), etc., and the second transfer arm 192 may be configured as a robot supporting the substrate S and moving the substrate S.

The atmospheric transfer module 190 may be connected to the load lock chamber 180, and the load lock chamber 180 may be connected to the transfer chamber 200 in which a first transfer arm 210 is disposed.

The load lock chamber 180 may include a first gate valve 184 provided between the atmospheric transfer module 190 and the load lock chamber 180 and a second gate valve 182 provided between the transfer chamber 200 and the load lock chamber 180.

The inside of the load lock chamber 180 may be maintained in a vacuum state by the first gate valve 184 and the second gate valve 182.

In addition, by opening and closing the first gate valve 184 and the second gate valve 182, the substrate S may be transferred from the atmospheric transfer module 190 to the transfer chamber 200 or from the transfer chamber 200 to the atmospheric transfer module 190.

Meanwhile, the transfer chamber 200 described above is connected to the plurality of process chambers 112, 114, 132, 134, 152, and 154.

A third gate valve 160 may be provided between the transfer chamber 200 and the process chambers 112, 114, 132, 134, 152, and 154.

The plurality of process chambers 112, 114, 132, 134, 152, and 154 may include, for example, the six process chambers 112, 114, 132, 134, 152, and 154.

In this case, the six process chambers 112, 114, 132, 134, 152, and 154 may be divided into three pairs of process chambers 112, 114: 132, 134: 152, and 154, and a pair of substrates S may be loaded together into a pair of process chambers 112, 114: 132, 134: and 152, 154 so that processes may be simultaneously performed and unloaded.

The first transfer arm 210 may include a pair of first transfer hands 220 and a pair of second transfer hands 230.

Any one of the first transfer hand 220 and the second transfer hand 230 may transfer the substrate S on which a processing process is not performed, and the other one may transfer the substrate S on which the processing process is completed.

The configurations of the process chambers 112, 114, 132, 134, 152, and 154 and the first transfer arm 210 are merely described as an example and may be appropriately modified.

On the other hand, with respect to the apparatus according to the related art, equipment depositing a thin film on the upper surface of a substrate and equipment depositing a thin film on the lower surface of the substrate are separately provided.

Therefore, a large area is required to install the equipment, and a significant amount of time is also required for the process.

In particular, when the substrate is transferred from the equipment depositing the thin film on the upper surface of the substrate to the equipment depositing the thin film on the lower surface of the substrate, the substrate is taken out from a vacuum environment inside a chamber of each equipment and transferred to a chamber of another apparatus.

In this case, a lot of time is required to build an environment inside the chamber, and in particular, a lot of time is required to build the vacuum environment inside the chamber.

The substrate processing apparatus 1000 according to the present invention is designed to solve the above problems, and at least some of the plurality of process chambers 112, 114, 132, 134, 152, and 154 may deposit a thin film on the lower surface of the substrate S.

That is, some of the plurality of process chambers 112, 114, 132, 134, 152, and 154 may deposit a thin film on the upper surface of the substrate S, and furthermore, the others of the plurality of process chambers 112, 114, 132, 134, 152, and 154 may deposit a thin film on the lower surface of the substrate S.

As a result, the substrate processing apparatus 1000 according to the present invention may include the process chambers 112, 114, 152, and 154 for depositing a thin film on the upper surface of the substrate S and the process chambers 132 and 134 for depositing a thin film on the lower surface of the substrate S in one apparatus.

Therefore, it is possible to solve the problems according to the related art described above.

Hereinafter, for convenience of description, process chambers for depositing a thin film on the upper surface of the substrate S are referred to as the first process chambers 112, 114, 152, and 154, and process chambers for depositing a thin film on the lower surface of the substrate S are referred to as the second process chambers 132 and 134.

In an embodiment, the first process chambers 112, 114, 152, and 154 may be implemented as chambers for depositing a hard mask layer (e.g., an amorphous carbon layer).

In addition, in an embodiment, the process temperature of each of the first process chambers 112, 114, 152, and 154 for depositing the hard mask layer on the upper surface of the substrate may be a high temperature of 600 degrees or more, and the process temperature of the first process chambers 132 and 134 for depositing a stress compensation layer on the lower surface of the substrate may be 400 degrees to 500 degrees.

In this case, the number of the second process chambers 132 and 134 is the same as the number of the first process chambers 112, 114, 152 and 154, or the number of the second process chambers 132 and 134 may be less than the number of the first process chambers 112, 114, 152, and 154.

That is, the number of the second process chambers 132 and 134 may be less than or equal to the number of the first process chambers 112, 114, 152 and 154.

The process time required for the second process chambers 132 and 134 to deposit the thin film on the lower surface of the substrate S may be less than the process time required to deposit the thin film on the upper surface of the substrate S.

This is because the second process chambers 132 and 134 deposits a thin film to alleviate or eliminate a bowing phenomenon generated in the substrate S so that the process of the second process chambers 132 and 134 may be performed faster than the process of the first process chambers 112, 114, 152, and 154.

Therefore, in the substrate processing apparatus 1000, the number of the second process chambers 132 and 134 may be less than or equal to the number of the first process chambers 112, 114, 152 and 154, and preferably the number of second process chambers 132 and 134 may be less than the number of the first process chambers 112, 114, 152 and 154.

With such a configuration, a delay time waiting for a substrate without processing being performed in the process chamber may be reduced.

In the present invention, for example, process chambers connected to the opposite side of the load lock chamber 180 in the transfer chamber 200 may correspond to the second process chambers 132 and 134.

Furthermore, process chambers connected to the left and right sides of the transfer chamber 200 may correspond to the first process chambers 112, 114, 152, and 154.

In this case, the second process chambers 132 and 134 may be disposed without being biased to either side with respect to the first process chambers 112, 114, 152, and 154.

Alternatively, the first process chambers 112, 114, 152, and 154 may be disposed substantially symmetrically with respect to the second process chambers 132 and 134.

In such an arrangement structure, the time taken to transfer the substrate S from the first process chamber 112, 114, 152, and 154 to the second process chamber 132 and 134, or from the second process chamber 132 and 134 to the first process chamber 112, 114, 152, and 154 may be reduced.

However, the arrangement of the second process chambers 132 and 134 described above has been described as an example and may be appropriately modified.

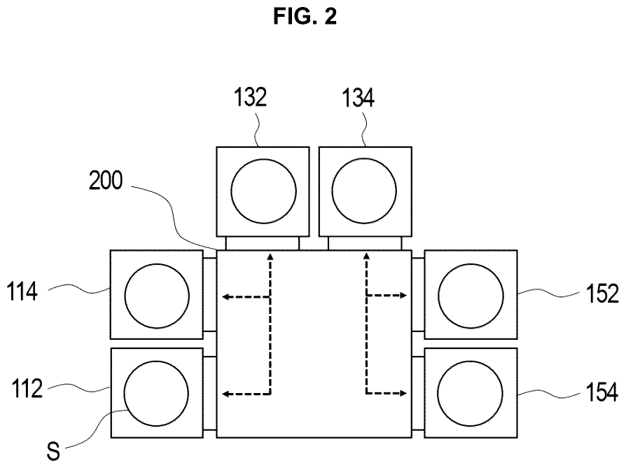

FIG. 2 is a schematic plan view of the substrate processing apparatus 1000 of FIG. 1. In FIG. 2, the transfer chamber 200 and the process chambers 112, 114, 132, 134, 152, and 154 are mainly shown.

Referring to FIG. 2, the substrate S may be transferred between the first process chambers 112, 114, 152, and 154 and the second process chambers 132 and 134 so that a process may be performed.

For example, a process of depositing a thin film on the upper surface of the substrate S may be referred to as a first processing process, and a process of depositing a thin film on the lower surface of the substrate S may be defined as a second processing process.

In this case, the first processing process and the second processing process may be alternately performed on the substrate S.

For example, the first processing process may be performed first and then the second processing process may be performed to alternately perform the process, or the second processing process may be performed first and then the first processing process may be performed to repeatedly perform the process alternately.

Alternatively, while the first processing process and the second processing process are alternately performed on the substrate S, any one processing process may be repeatedly performed twice or more.

For example, when the first processing process is performed first and then the second processing process is performed, the second processing process may be repeatedly performed twice or more, and then the first processing process may be performed again.

Alternatively, the first processing process may be first performed twice or more, and then the second processing process may be performed to alternately perform the process.

On the other hand, the control unit 300 described above controls to select and perform the first processing process or the second processing process when the process is performed on the substrate S.

For example, the control unit 300 may sense the thickness of the thin film on the upper or lower surface of the substrate S or the degree of bowing of the substrate S to control the process on the substrate S.

In this case, the substrate processing apparatus 1000 may include a sensing means (not shown) for sensing the substrate S.

The sensing means may be provided in the load lock chamber 180, the transfer chamber 200, or the various gate valves 182, 184, and 160 described above.

Therefore, the control unit 300 may control to select and proceed with the first processing process or the second processing process when the process is performed on the substrate S according to the sensing information transmitted from the sensing unit.

Meanwhile, in another embodiment, the control unit 300 may include a storage unit (not shown) capable of receiving and storing various types of data of the substrate S.

The storage unit may store various types of information about the substrate S to be processed by the substrate processing apparatus 1000, for example, information about the size, diameter, and thickness of the substrate S, a preprocessing process already performed on the substrate S, a post-processing process to be performed later on the substrate S, etc.

In addition, the storage unit may also store information about the degree of bowing of the substrate S according to the pre-processing process already performed on the substrate S or the expected degree of bowing of the substrate S according to the post-processing process to be performed later on the substrate S together.

Accordingly, the control unit 300 may adjust the order and the number of repetitions of the first processing process of the first process chambers 112, 114, 152, and 154 and the second processing process of the second process chambers 132 and 134 on the substrate S based on the various types of information about the substrate S stored in the storage unit.

When the control unit 300 includes the storage unit, the sensing means described above may be omitted, and the control unit 300 may include the storage unit and the sensing means together.

In addition, the controller 300 may alternately repeat the first processing process of the first process chambers 112, 114, 152, and 154 and the second processing process of the second process chambers 132 and 134 on the substrate S so that the amorphous carbon layer described above is deposited on the upper surface of the substrate S to a desired thickness.

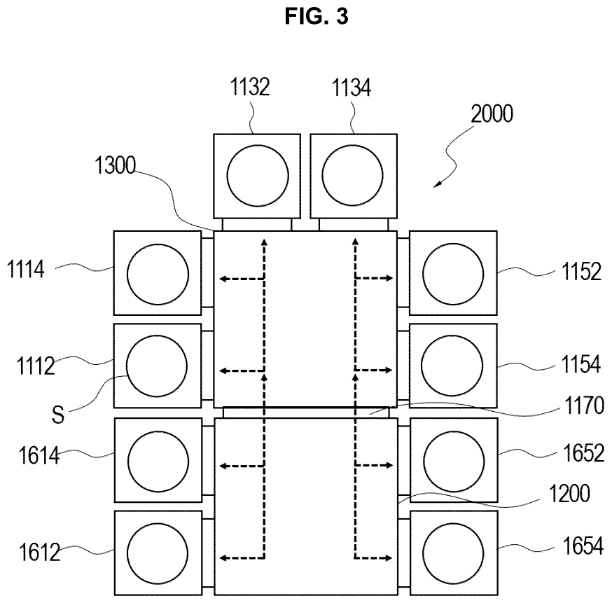

Meanwhile, FIG. 3 is a plan view illustrating transfer chambers 1200 and 1300 and process chambers 1612, 1614, 1652, 1654, 1112, 1114, 1132, 1134, 1152, and 1154 in a substrate processing apparatus 2000 according to another embodiment.

Only the transfer chambers 1200 and 1300 and the process chambers 1612, 1614, 1652, 1654, 1112, 1114, 1132, 1134, 1152, and 1154 are shown in FIG. 3 and the configurations such as the load lock chamber 180 and the atmospheric transfer module 190 are omitted.

Referring to FIG. 3, the substrate processing apparatus 2000 according to the present embodiment may include the two or more transfer chambers 1200 and 1300 which are connected and disposed.

For example, the substrate processing apparatus 2000 may include the first transfer chamber 1200 connected to a load lock chamber (not shown) and the second transfer chamber 1300 connected to the first transfer chamber 1200 via an intermediate gate valve 1170.

The number of the transfer chambers 1200 and 1300 connected to each other is shown as two as described above, but is not limited thereto and may be appropriately modified and increased.

A first side of the first transfer chamber 1200 may be connected to the load lock chamber (not shown), and a second side (or left side) and a third side (or right side) of the first transfer chamber 1200 may be connected the process chambers 1612, 1614, 1652, and 1654.

In addition, a fourth side of the first transfer chamber 1200 facing the first side may be connected to the second transfer chamber 1300 via the intermediate gate valve 1170.

Meanwhile, a first side of the second transfer chamber 1300 may be connected to the first transfer chamber 1200 via the intermediate gate valve 1170, and a second side (or left side), a third side (or right side) and a fourth side of the second transfer chamber 1300 may be connected to the process chambers 1112, 1114, 1132, 1134, 1152, and 1154.

In the substrate processing apparatus 2000 according to the above configuration, process chambers connected to the fourth side of the second transfer chamber 1300 may be configured as the second process chambers 1132 and 1134.

That is, the first process chambers 1612, 1614, 1652, and 1654 may be connected to the second side (or left side) and the third side (or right side) of the first transfer chamber 1200, the first process chambers 1112, 1114, 1152, and 1154 may be connected to the second side (or left side) and the third side (or right side) of the second transfer chamber 1300, and the second process chambers 1132 and 1134 may be connected to the fourth side of the second transfer chamber 1300 facing the load lock chamber.

In this case, the first process chambers 1612, 1614, 1652, 1654, 1112, 1114, 1152, and 1154 may be disposed substantially symmetrically with respect to the second process chambers 1132 and 1134.

In such an arrangement, a moving distance or a moving time of the substrate S between the first process chambers 1612, 1614, 1652, 1654, 1112, 1114, 1152, and 1154 and the second process chambers 1132 and 1134 may be reduced as much as possible.

Meanwhile, the number and positions of the second process chambers 1132 and 1134 in the substrate processing apparatus 2000 according to FIG. 3 have been described as an example and may be appropriately modified.

In the substrate processing apparatus 2000 according to the present embodiment, a process including the first processing process and the second processing process on the substrate S is similar to that of the above-described embodiment, and thus, a repeated description thereof will be omitted.

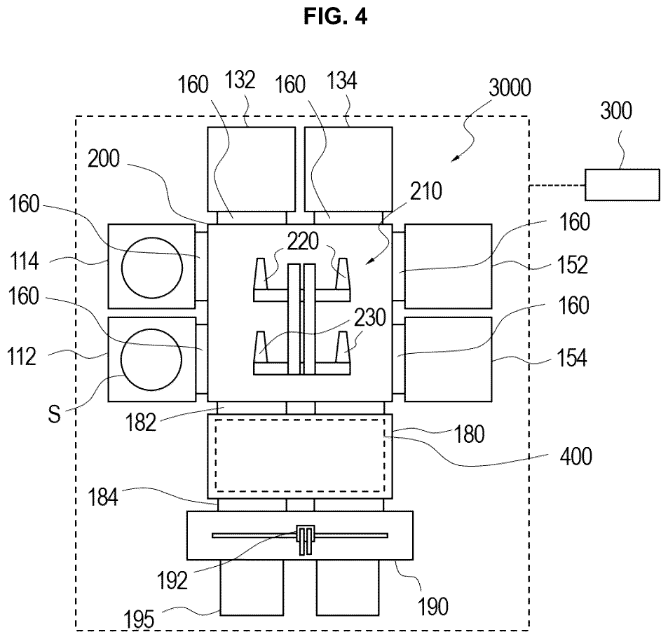

Meanwhile, FIG. 4 is a plan view illustrating a substrate processing apparatus 3000 according to another embodiment of the present invention.

In the substrate processing apparatus 3000 according to the present embodiment, the same reference numerals are used for the same components compared to the embodiment of FIG. 1.

Referring to FIG. 4, the load lock chamber 180 of the substrate processing apparatus 3000 may include a temperature controller 400 for controlling the temperature of the substrate S.

The temperature controller 400 may control the temperature of the substrate S passing through the load lock chamber 180 or the substrate S introduced into the load lock chamber 180.

The temperature of the substrate S controlled by the temperature controller 400 may be appropriately changed.

For example, in the present embodiment, the temperature of the substrate S may be controlled to approximately 400° C. by the temperature controller 400.

The temperature controller 400 may be implemented in various forms.

For example, the temperature controller 400 may be implemented in the form of a lamp or a heater provided in the load lock chamber 180, or may supply a cooling or heating gas.

A specific form of the temperature controller 400 is not specifically limited in the present specification.

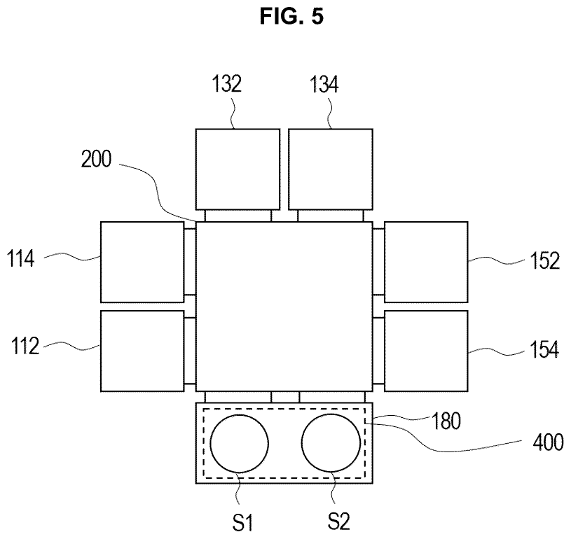

FIG. 5 is a schematic plan view illustrating the substrate processing apparatus 3000 of FIG. 4. In FIG. 5, the transfer chamber 200 and the process chambers 112, 114, 132, 134, 152, and 154 are mainly shown.

Referring to FIG. 5, substrates S1 and S2 may be transferred between the first process chambers 112, 114, 152, and 154 and the second process chambers 132 and 134 so that a process may be performed.

For example, a process of depositing a thin film on upper surfaces of the substrates S1 and S2 may be referred to as a first processing process, and a process of depositing a thin film on lower surfaces of the substrates S1 and S2 may be defined as a second processing process.

In this case, the first processing process and the second processing process may be alternately performed on the substrates S1 and S2.

For example, the first processing process may be performed first and then the second processing process may be performed to alternately perform the process, or the second processing process may be performed first and then the first processing process may be performed to repeatedly perform the process alternately.

Alternatively, while the first processing process and the second processing process are alternately performed on the substrates S1 and S2, any one processing process may be repeatedly performed twice or more.

For example, when the first processing process is performed first and then the second processing process is performed, the second processing process may be repeatedly performed twice or more, and then the first processing process may be performed again.

Alternatively, the first processing process may be first performed twice or more, and then the second processing process may be performed to alternately perform the process.

Meanwhile, the control unit 300 described above controls to select and perform the first processing process or the second processing process when the process is performed on the substrates S1 and S2.

For example, the control unit 300 may sense the thickness of the thin film on the upper or lower surface of the substrates S1 and S2 or the degree of bowing of the substrates S1 and S2 to control the process on the substrates S1 and S2.

In this case, the substrate processing apparatus 3000 may include a sensing means (not shown) for sensing the substrates S1 and S2.

The sensing means may be provided in the load lock chamber 180, the transfer chamber 200, or the various gate valves 182, 184, and 160 described above.

Meanwhile, in another embodiment, the control unit 300 may include a storage unit (not shown) capable of receiving and storing various types of data of the substrates S1 and S2.

The storage unit may store various types of information about the substrates S1 and S2 to be processed by the substrate processing apparatus 3000, for example, information about the sizes, diameters, and thicknesses of the substrates S1 and S2, a preprocessing process already performed on the substrates S1 and S2, a post-processing process to be performed later on the substrates S1 and S2, etc.

In addition, the storage unit may also store information about degrees of bowing of the substrates S1 and S2 according to the pre-processing process already performed on the substrates S1 and S2 or expected degrees of bowing of the substrates S1 and S2 according to the post-processing process to be performed later on the substrates S1 and S2 together.

Accordingly, the control unit 300 may adjust the order and the number of repetitions of the first processing process of the first process chambers 112, 114, 152, and 154 and the second processing process of the second process chambers 132 and 134 on the substrates S1 and S2 based on the various types of information about the substrates S1 and S2 stored in the storage unit.

When the control unit 300 includes the storage unit, the sensing means described above may be omitted, and the control unit 300 may include the storage unit and the sensing means together.

Hereinafter, steps of performing the process on the substrates S1 and S2 by the substrate processing apparatus 3000 will be described with reference to FIGS. 5 to 7.

First, the substrates S1 and S2 before being introduced into the load lock chamber 180 may have approximately a room temperature, and a stress (a compressive stress or a tensile stress) applied to the substrates S1 and S2 may be approximately 150 MPa or less.

The substrates S1 and S2 having the above conditions may be introduced into the load lock chamber 180 as shown in FIG. 5 and preheated to a first temperature by the temperature controller 400.

In this case, the first temperature may be appropriately adjusted according to process conditions with respect to the substrates S1 and S2.

For example, when the first processing process of depositing a thin film on the upper surfaces of the substrates S1 and S2 is a process of depositing a hard mask layer at a high temperature of 550° C. to 650° C., the first temperature may be determined to be approximately 400° C.

That is, the substrates S1 and S2 may be preheated to the first temperature in the load lock chamber 180, and a considerable portion of the stress of the substrates S1 and S2 may be relieved by the preheating step.

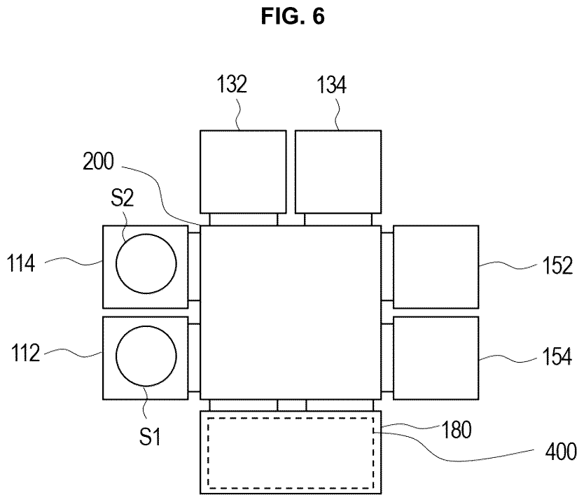

Subsequently, the substrates S1 and S2 may be transferred to the first process chambers 112 and 114, as shown in FIG. 6, and the first processing process of depositing a thin film on the upper surfaces of the substrates S1 and S2 may be performed.

In this case, the first processing process may correspond to a process of depositing a hard mask layer at a high temperature of 550° C. to 650° C. as described above.

As such, when a thin film is deposited on the upper surfaces of the substrates S1 and S2, the stress applied to the substrates S1 and S2 may increase, for example, to 250 Mpa or more.

When the stress applied to the substrates S1 and S2 further increases, the degree of bending of the substrates S1 and S2 increases, and thus, chucking of an electrostatic chuck (not shown) fixing the substrates S1 and S2 may be released.

Therefore, in the present invention, as shown in FIG. 5 after the first processing process, the substrates S1 and S2 may be transferred to the load lock chamber 180 again and cooled to a second temperature.

The stress applied to the substrates S1 and S2 may be alleviated by cooling the substrates S1 and S2 to the second temperature.

In this case, the second temperature may be set in various ways. For example, the second temperature may be set to be equal to the first temperature.

That is, the second temperature may be set to about 400° C. and is lower than the process temperature of the first processing process, and thus, a process processed at the second temperature may be referred to as a cooling process.

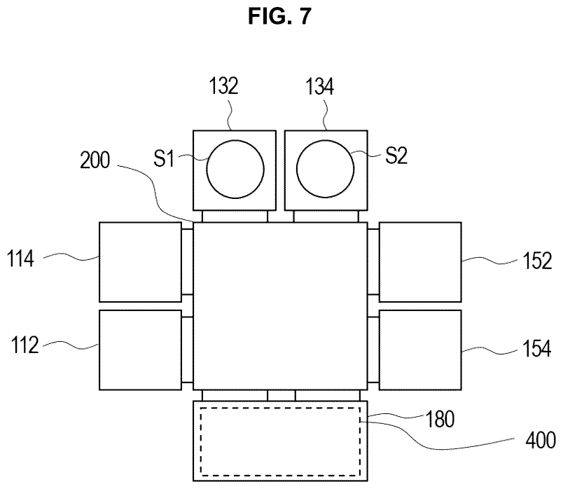

Subsequently, the substrates S1 and S2 may be transferred to the second process chambers 132 and 134, as shown in FIG. 7, and the second processing process of depositing a stress compensation thin film on the lower surfaces of the substrates S1 and S2 may be performed.

As described above, the process temperature of the second processing process may correspond to approximately 400° C. to 550° C.

The stress remaining in the substrates S1 and S2 after the cooling step may be relieved by the second processing process.

For example, the stress applied to the substrates S1 and S2 on which the second processing process is performed may be approximately 150 Mpa or less.

After the second processing process, a step of transferring the substrates S1 and S2 to the first process chambers 112 and 114 and performing the first processing process may be repeated if necessary.

After repeating the first processing process, the processing process on the substrates S1 and S2 may end.

Alternatively, after repeating the first processing process, a step of cooling the substrates S1 and S2, performing the second processing process of depositing a stress compensation film on the lower surfaces of the substrates S1 and S2, and performing the first processing process on the substrates S1 and S2 may be repeated.

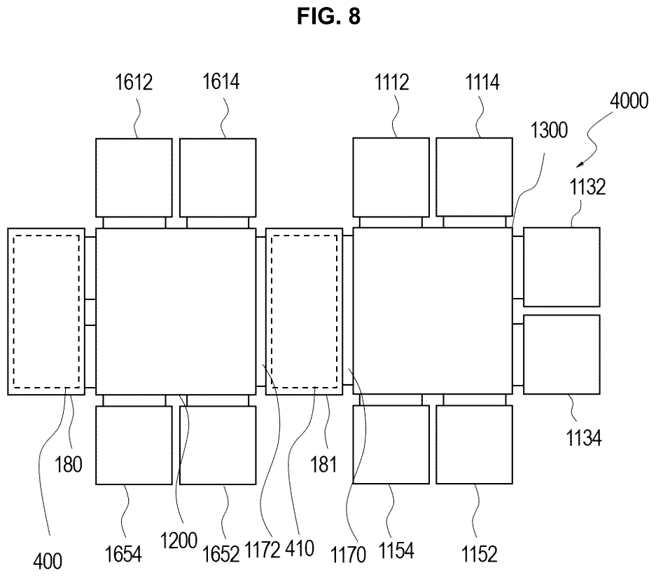

Meanwhile, FIG. 8 is a plan view illustrating the transfer chambers 1200 and 1300 and the process chambers 1612, 1614, 1652, 1654, 1112, 1114, 1132, 1134, 1152, and 1154 in a substrate processing apparatus 4000 according to another embodiment.

In FIG. 8, the same reference numerals are used for the same components compared to the embodiment of FIG. 3 described above.

The transfer chambers 1200 and 1300, the process chambers 1612, 1614, 1652, 1654, 1112, 1114, 1132, 1134, 1152, and 1154, and the load lock chamber 180 are shown in FIG. 8, and the configuration such as the atmospheric transfer module 190 are omitted.

Referring to FIG. 8, the substrate processing apparatus 4000 according to the present embodiment may include the two or more transfer chambers 1200 and 1300 connected to each other and disposed.

For example, the substrate processing apparatus 4000 may include the first transfer chamber 1200 connected to the load lock chamber 180 and the second transfer chamber 1300 connected to the first transfer chamber 1200 via intermediate gate valves 1170 and 1172 and an intermediate load lock chamber 181.

The number of transfer chambers 1200 and 1300 connected to each other is shown as two as described above, but is not limited thereto and may be appropriately modified and increased.

Meanwhile, the load lock chamber 180 and the intermediate load lock chamber 181 may include temperature controllers 400 and 410, respectively, similarly to the above-described embodiment.

For example, the load lock chamber 180 may include the first temperature controller 400 and the intermediate load lock chamber 181 may include the second temperature controller 410.

The temperature controllers 400 and 410 have been described above, and thus, repeated descriptions thereof will be omitted.

A first side of the first transfer chamber 1200 may be connected to the load lock chamber 180, and second and third sides of the first transfer chamber 1200 may be connected to the process chambers 1612, 1614, 1652, and 1654.

In addition, a fourth side of the first transfer chamber 1200 facing the first side may be connected to the second transfer chamber 1300 via the intermediate gate valves 1170 and 172 and the intermediate load lock chamber 181.

Meanwhile, a first side of the second transfer chamber 1300 may be connected to the first transfer chamber 1200 via the intermediate gate valves 1170 and 1172, and a second side, a third side, and a fourth side of the second transfer chamber 1300 may be connected to the process chambers 1112, 1114, 1132, 1134, 1152, and 1154.

In the substrate processing apparatus 4000 according to the above configuration, process chambers connected to the fourth side of the second transfer chamber 1300 may be configured as the second process chambers 1132 and 1134.

That is, the first process chambers 1612, 1614, 1652, and 1654 may be connected to the second and third sides of the first transfer chamber 1200, the first process chambers 1112, 1114, 1152, and 1154 may be connected to the second and third sides of the second transfer chamber 1300, and the second process chambers 1132 and 1134 may be connected to the fourth side of the second transfer chamber 1300 facing the intermediate load lock chamber 181.

In this case, the first process chambers 1612, 1614, 1652, 1654, 1112, 1114, 1152, and 1154 may be disposed substantially symmetrically with respect to the second process chambers 1132 and 1134.

In such an arrangement, a moving distance or a moving time of the substrate S between the first process chambers 1612, 1614, 1652, 1654, 1112, 1114, 1152, and 1154 and the second process chambers 1132 and 1134 may be reduced as much as possible.

Meanwhile, the number and positions of the second process chambers 1132 and 1134 in the substrate processing apparatus 4000 according to FIG. 8 have been described as an example and may be appropriately modified.

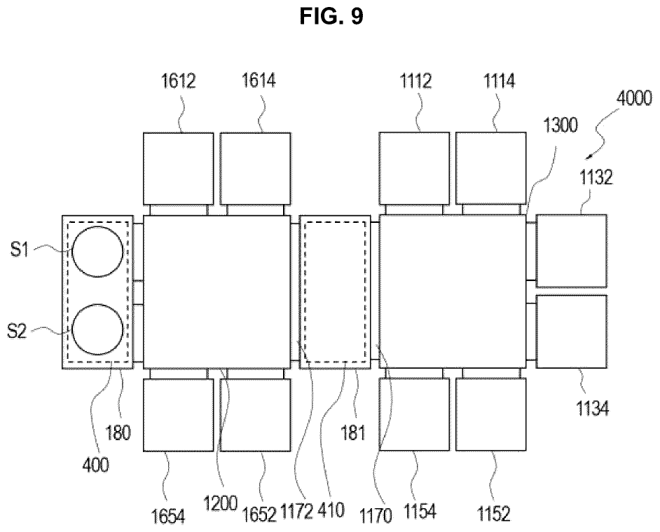

Hereinafter, steps of performing the process on the substrates S1 and S2 by the substrate processing apparatus 4000 will be described with reference to FIGS. 9 to 13.

First, the substrates S1 and S2 before being introduced into the load lock chamber 180 may have approximately a room temperature, and a stress (a compressive stress or a tensile stress) applied to the substrates S1 and S2 may be approximately 150 MPa or less.

The substrates S1 and S2 having the above conditions may be introduced into the load lock chamber 180 as shown in FIG. 9 and preheated to a first temperature by the temperature controller 400.

In this case, the first temperature may be appropriately adjusted according to process conditions with respect to the substrates S1 and S2.

For example, when the first processing process of depositing a thin film on the upper surfaces of the substrates S1 and S2 is a process of depositing a hard mask layer at a high temperature of 550° C. to 650° C., the first temperature may be determined to be approximately 400° C.

That is, the substrates S1 and S2 may be preheated to the first temperature in the load lock chamber 180, and the stress of the substrates S1 and S2 may be relieved by the preheating step.

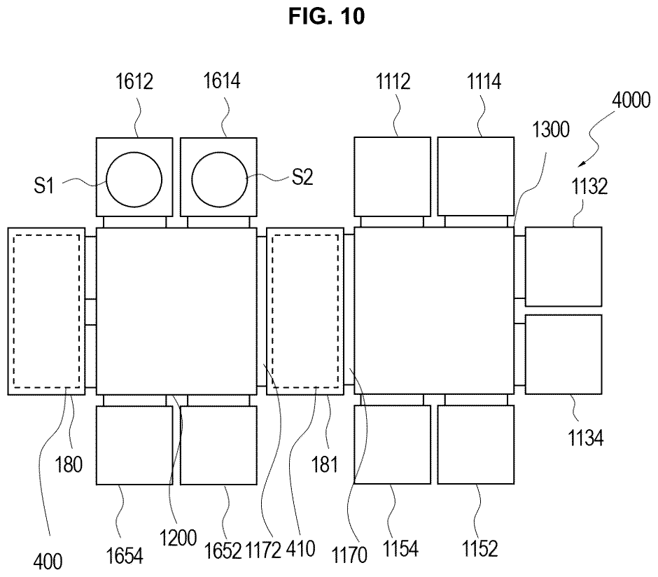

Subsequently, the substrates S1 and S2 may be transferred to the first process chambers 1612 and 1624, as shown in FIG. 10, and the first processing process of depositing a thin film on the upper surfaces of the substrates S1 and S2 may be performed.

In this case, the first processing process may correspond to a process of depositing a hard mask layer at a high temperature of 550° C. to 650° C. as described above.

As such, when a thin film is deposited on the upper surfaces of the substrates S1 and S2, the stress applied to the substrates S1 and S2 may increase, for example, to 250 Mpa or more.

When the stress applied to the substrates S1 and S2 further increases, the degree of bending of the substrates S1 and S2 increases, and thus, chucking of an electrostatic chuck (not shown) fixing the substrates S1 and S2 may be released.

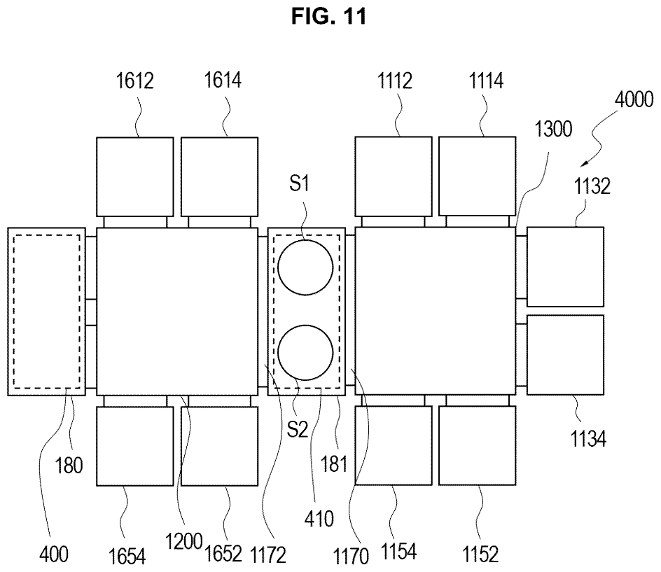

Therefore, in the present invention, as shown in FIG. 11 after the first processing process, the substrates S1 and S2 may be transferred to the load lock chamber 180 again and cooled to a second temperature.

In the present embodiment, since the intermediate load lock chamber 181 is provided, the cooling step is performed by transferring the substrates S1 and S2 to the intermediate load lock chamber 181 at the rear without transferring the substrates S1 and S2 to the load lock chamber 180 at the front, in order to perform the cooling step.

As a result, a process on another substrate may be performed through the load lock chamber 180, and thus, the process speed with respect to the substrate may be increased, and throughput may be improved.

The stress applied to the substrates S1 and S2 may be alleviated by cooling the substrates S1 and S2 to the second temperature.

In this case, the second temperature may be set in various ways. For example, the second temperature may be set to be the same as the first temperature.

That is, the second temperature may be set to about 400° C. and is lower than the process temperature of the first processing process, and thus, a process processed at the second temperature may be referred to as a cooling process.

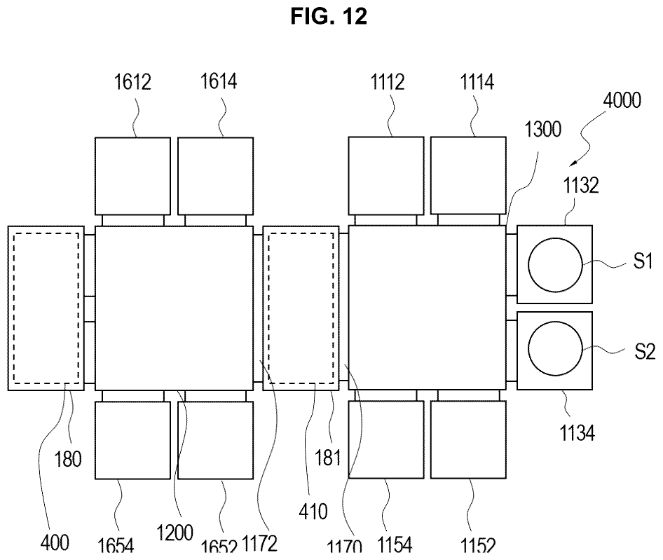

Subsequently, the substrates S1 and S2 may be transferred to the second process chambers 1132 and 1134, as shown in FIG. 12, and the second processing process of depositing a stress compensation thin film on the lower surfaces of the substrates S1 and S2 may be performed.

As described above, the process temperature of the second processing process may correspond to approximately 400° C. to 550° C.

The stress remaining in the substrates S1 and S2 after the cooling step may be relieved by the second processing process.

For example, the stress applied to the substrates S1 and S2 on which the second processing process is performed may be approximately 150 Mpa or less.

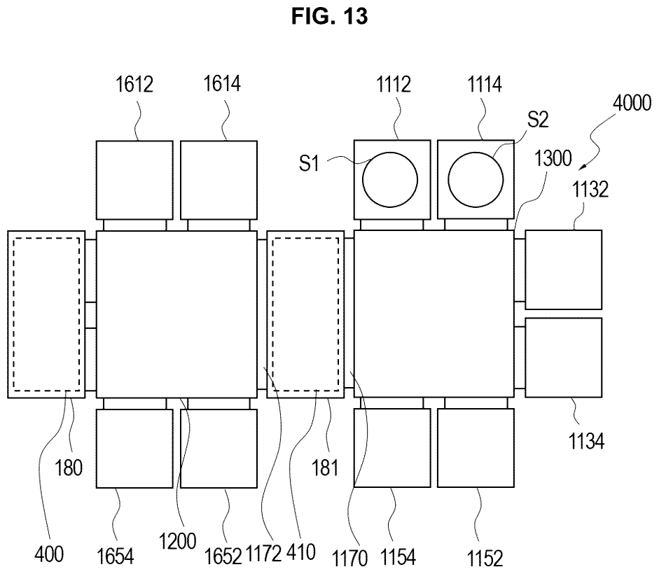

After the second processing process, a step of transferring the substrates S1 and S2 to the first process chambers 1112 and 1114 as shown in FIG. 13 and performing the first processing process may be repeated if necessary.

When the first processing process is repeated, the first processing process may be performed by the first process chambers 1112, 1114, 1154, and 1152 connected to the second transfer chamber 1300 other than the first process chambers 1612, 1614, 1654, and 1652 connected to the first transfer chamber 1200.

As a result, by shortening the moving distance of the substrates S1 and S2, the time required for the process may be reduced, and the processing process on the substrates S1 and S2 may be performed more efficiently.

After repeating the first processing process, the processing process on the substrates S1 and S2 may end.

Alternatively, after repeating the first processing process, a step of cooling the substrates S1 and S2, performing the second processing process of depositing a stress compensation film on the lower surfaces of the substrates S1 and S2, and performing the first processing process on the substrates S1 and S2 may be repeated.

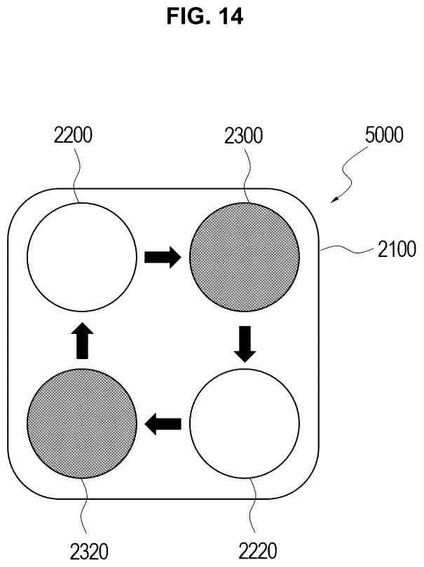

Meanwhile, FIG. 14 is a plan view of a substrate processing apparatus 5000 according to another embodiment.

Referring to FIG. 14, the substrate processing apparatus 5000 according to the present embodiment may include a plurality of stations 2200, 2220, 2300, and 2320 processing a substrate inside one chamber 2100.

That is, as shown in FIG. 14, the substrate processing apparatus 5000 may include the plurality of stations 2200, 2220, 2300, and 2320 in which the substrate is seated and processed inside the chamber 2100.

In the figure, the four stations 2200, 2220, 2300, and 2320 are shown, but this is only an example, and the number of the stations 2200, 2220, 2300, and 2320 may be appropriately modified.

Meanwhile, an inlet (not shown) into which the substrate is introduced and an outlet (not shown) through which the substrate is taken out may be formed at one side of the chamber 2100.

In addition, a spider (not shown) moving the substrate between the stations 2200, 2220, 2300, and 2320 may be disposed at a substantially central portion of the chamber 2100.

The spider is disposed at the central portion of the chamber 2100 to be able to rotate and lift, and serves to move the substrate S between the stations 2200, 2220, 2300 and 2320.

As described above, when the plurality of stations 2200, 2220, 2300, and 2320 are included in the single chamber 2100, a means partitioning between the stations 2200, 2220, 2300, and 2320 according to processes may be required.

That is, when different processes are performed between the neighboring stations 2200, 2220, 2300, and 2320, it is necessary to partition the stations 2200, 2220, 2300, and 2320 in order not to reduce the efficiency of processes and not to affect processes of the other stations 2200, 2220, 2300, and 2320.

Such partition means may be implemented in various forms.

For example, a curtain gas such as an inert gas may be supplied between the plurality of stations 2200, 2220, 2300, and 2320 to partition the stations 2200, 2220, 2300, and 2320.

In this case, the inert gas may be supplied toward the inside of the chamber 2100 from at least one of the floor, ceiling, and side surface of the chamber 2100.

Also, by supplying the inert gas to the central portion of the chamber 2100, the stations 2200, 2220, 2300, and 2320 may be more reliably partitioned.

As such, when the inert gas is supplied, an exhaust means exhausting a residual gas including the inert gas described above may be connected to the chamber 2100.

Meanwhile, the plurality of stations 2200, 2220, 2300, and 2320 may be physically partitioned.

In this case, when the stations 2200, 2220, 2300, and 2320 are completely isolated by a blocking plate, because it is impossible to move the substrate between the stations 2200, 2220, 2300, and 2320, the plurality of stations 2200, 2220, 2300 and 2320 may be partitioned from each other, but the movement of the substrate may be partitioned in a so-called ‘semi-enclosed or semi-isolated’ manner as much as possible.

For example, even when the stations 2200, 2220, 2300, and 2320 are partitioned by the blocking plate, the blocking plate may include an opening through which the movement of the substrate is possible.

Due to such an opening, the plurality of stations 2200, 2220, 2300, and 2320 may not be completely isolated but may maintain a semi-enclosed or semi-isolated state.

Meanwhile, at least some of the plurality of stations 2200, 2220, 2300, and 2320 may deposit a thin film on the lower surface of the substrate.

That is, the stations 2200 and 2220 among the plurality of stations 2200, 2220, 2300, and 2320 may deposit a thin film on the upper surface of the substrate, and furthermore, the other stations 2300 and 2320 may deposit a thin film on the lower surface of the substrate.

As a result, the substrate processing apparatus 5000 according to the present embodiment may include the stations 2200 and 2220 for depositing the thin film on the upper surface of the substrate and the stations 2300 and 2320 for depositing the thin film on the lower surface of the substrate inside one chamber 2100 together.

Hereinafter, for convenience of description, stations performing a first processing process of depositing a thin film on the upper surface of the substrate are referred to as the first stations 2200 and 2220, and stations performing a second processing process of depositing a thin film on the lower surface of the substrate are referred to as the second stations 2300 and 2320.

In the substrate processing apparatus 5000 according to FIG. 14, the first stations 2200 and 2220 and the second stations 2300 and 2320 may be alternately disposed inside the chamber 2100.

That is, the first stations 2200 and 2220 and the second stations 2300 and 2320 may be sequentially disposed inside the chamber 2100 in one direction.

In this case, while the substrate is moved between the stations 2200, 2220, 2300, and 2320 by the spider described above, the stations 2200, 2220, 2300, and 2320 may perform the first processing process or the second processing process.

In addition, in the substrate processing apparatus 5000 according to the present embodiment, a control unit may alternately repeat the first processing process of the first stations 2200 and 2220 and the second processing process of the second stations 2300 and 2320 on the substrate so that an amorphous carbon layer is deposited on the upper surface of the substrate to a desired thickness.

Adjustment of the order and number of repetitions of the first processing process and the second processing process performed by the control unit on the substrate S is similar to that of the above-described embodiments, and thus, a repeated description thereof is omitted.

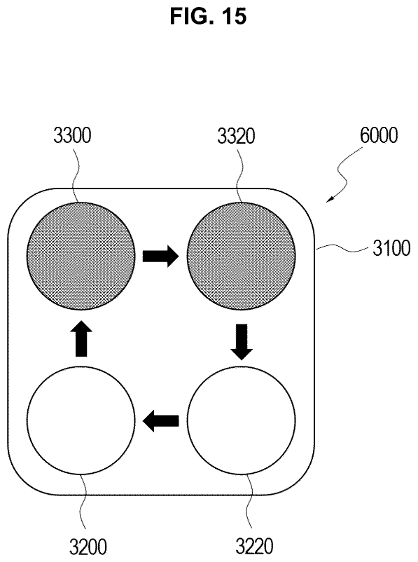

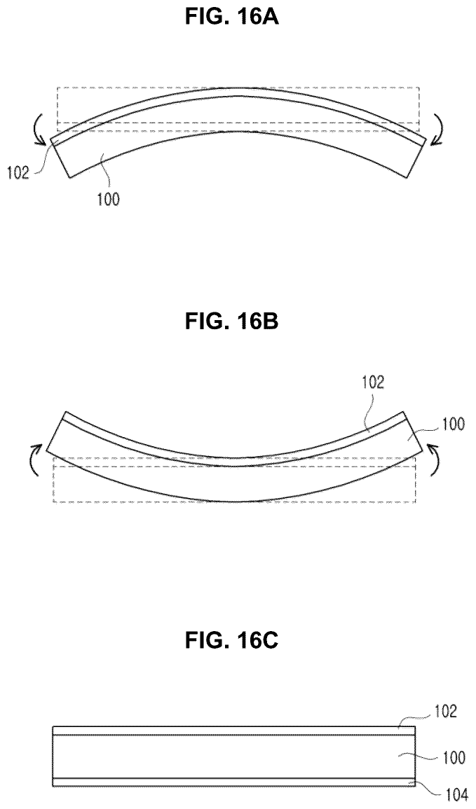

Meanwhile, FIG. 15 is a plan view of a substrate processing apparatus 6000 according to another embodiment.

Referring to FIG. 15, a substrate processing apparatus 6000 according to the present embodiment may include a plurality of stations 3200, 3220, 3300, and 3320 processing a substrate inside one chamber 3100, and the first stations 3200 and 3220 and the second stations 3300 and 3320 may be continuously arranged inside the chamber 3100.

That is, the two or more first stations 3200 and 3220 and the two or more second stations 3300 and 3320 may be continuously arranged inside the chamber 3100 in one direction.

FIG. 15 shows a configuration in which the two first stations 3200 and 3220 and the two second stations 3300 and 3320 are continuously arranged, this is only an example and the configuration may be appropriately modified.

Adjustment of the order and number of repetitions of a first processing process and a second processing process performed by a control unit on the substrate S is similar to that of the above-described embodiments, and thus, a repeated description thereof is omitted.

According to the present invention having the above-described configuration, since both the upper and lower surfaces of the substrate are deposited in a single device or a single facility, an installation area of the apparatus may be reduced, and in particular, the time required to build an environment inside the chamber may be reduced, thereby significantly reducing the process time.

Although the invention has been described with reference to preferred embodiments of the present invention, those having ordinary skill in the art may modify and change the present invention in various ways within the scope without departing from the spirit and scope of the present invention described in the following claims.

Therefore, if the modified embodiment basically includes the components of the claims of the present invention, it should be considered that all of the components are included in the technical scope of the present invention.

What is claimed is:

1. A substrate processing apparatus for performing a processing process on a substrate, the substrate processing apparatus comprising:
a transfer chamber transferring the substrate;
a plurality of process chambers connected to the transfer chamber and performing the processing process on the substrate; and
a control unit controlling driving of the plurality of process chambers,
wherein some of the plurality of process chambers are configured as first process chambers depositing a thin film on an upper surface of the substrate, and the others are configured as second process chambers depositing a thin film on a lower surface of the substrate, and
the first process chambers are symmetrically arranged with respect to the second process chambers and connected to the transfer chamber.

2. The substrate processing apparatus of according to claim 1, wherein the number of the second process chambers is less than or equal to the number of the first process chambers.

3. The substrate processing apparatus of according to claim 1, wherein the control unit stores at least one of a size, a diameter, and a thickness of the substrate, information about a preprocessing process already performed on the substrate, information about a post-processing process to be performed later on the substrate, and information about a degree of bowing of the substrate according to the preprocessing process already performed on the substrate and an expected degree of bowing of the substrate according to the post-processing process to be performed later on the substrate, and
the control unit adjusts the order and the number of repetitions of a first processing process of the first process chambers and a second processing process of the second process chambers on the substrate based on the stored information about the substrate.

4. The substrate processing apparatus of according to claim 1, further comprising: a sensing means sensing a thickness of the thin film on the upper surface or the lower surface of the substrate or a degree of bowing of the substrate,
wherein the control unit adjusts the order and the number of repetitions of a first processing process of the first process chambers and a second processing process of the second process chambers on the substrate based on information sensed by the sensing means.

5. The substrate processing apparatus of according to claim 1, wherein an amorphous carbon layer is deposited on the upper surface of the substrate in the first process chambers.

6. The substrate processing apparatus of according to claim 5, wherein the control unit alternately repeats a first processing process of the first process chambers and a second processing process of the second process chambers on the substrate so that the amorphous carbon layer is deposited on the upper surface of the substrate to a desired thickness.

7. The substrate processing apparatus of according to claim 1, further comprising: a load lock chamber connected to the transfer chamber,
wherein a temperature controller controlling a temperature of the substrate is included in the load lock chamber.

8. A substrate processing apparatus for performing a processing process on a substrate, the substrate processing apparatus comprising:
a process chamber performing a processing process on the substrate;
a plurality of stations provided inside the process chamber in which the substrate is seated; and
a control unit controlling driving of the plurality of stations,
wherein some of the plurality of stations are configured as first stations depositing a thin film on an upper surface of the substrate, and the others are configured as second stations depositing a thin film on a lower surface of the substrate.

9. The substrate processing apparatus of according to claim 8, wherein the plurality of stations are partitioned by supplying a curtain gas such as an inert gas between the plurality of stations, or the plurality of stations are physically partitioned but are partitioned in a semi-enclosed or semi-isolated manner through which a movement of the substrate is possible.

10. The substrate processing apparatus of according to claim 8, wherein the control unit stores at least one of a size, a diameter, and a thickness of the substrate, information about a preprocessing process already performed on the substrate, information about a post-processing process to be performed later on the substrate, and information about a degree of bowing of the substrate according to the preprocessing process already performed on the substrate and an expected degree of bowing of the substrate according to the post-processing process to be performed later on the substrate, and
the control unit adjusts the order and the number of repetitions of a first processing process of the first process chambers and a second processing process of the second process chambers on the substrate based on the stored information about the substrate.

11. The substrate processing apparatus of according to claim 8, further comprising: a sensing means sensing a thickness of the thin film on the upper surface or the lower surface of the substrate or a degree of bowing of the substrate,
wherein the control unit adjusts the order and the number of repetitions of a first processing process of the first process chambers and a second processing process of the second process chambers on the substrate based on information sensed by the sensing means.

12. The substrate processing apparatus of according to claim 8, wherein the control unit alternately repeats a first processing process of the first process chambers and a second processing process of the second process chambers on the substrate so that an amorphous carbon layer is deposited on the upper surface of the substrate to a desired thickness.

13. A substrate processing method of a substrate processing apparatus comprising a load lock chamber comprising a temperature controller controlling a temperature of a substrate, one or more first process chambers connected to the load lock chamber and depositing a thin film on an upper surface of the substrate, and one or more second process chambers depositing a thin film on a lower surface of the substrate, the substrate processing method comprising:
preheating the substrate to a first temperature in the load lock chamber;
depositing the thin film on the upper surface of the substrate in the one or more first process chambers;
cooling the substrate to a second temperature in the load lock chamber; and
depositing a stress compensation layer on the lower surface of the substrate in the one or more second process chambers.

14. The substrate processing method of according to claim 13, wherein an amorphous carbon layer is deposited on the upper surface of the substrate in the one or more first process chambers.

15. The substrate processing method of according to claim 13, wherein a process temperature of each of the one or more second process chambers is lower than a process temperature of each of the one or more first process chambers.

16. The substrate processing method of according to claim 13, wherein the first temperature for preheating the substrate in the load lock chamber is lower than a process temperature of each of the one or more first process chambers.

17. The substrate processing method of according to claim 13, wherein the second temperature is equal to the first temperature.

18. The substrate processing method of according to claim 13, further comprising: after depositing the stress compensation layer on the lower surface of the substrate in the one or more second process chambers,
transferring the substrate to the one or more first process chambers and repeatedly depositing the thin film on the upper surface of the substrate.
